(19) United States
(12) Patent Application Publication
(10) Pub. No.: US 2026/0079214 A1
(43) Pub. Date: Mar. 19, 2026

(54) DEVICE AND METHOD FOR PREDICTING LIFE OF BATTERY

(71) Applicant: SAMSUNG SDI CO., LTD., Yongin-si (KR)

(72) Inventors: Junho JANG, Yongin-si (KR); Haemin KIM, Yongin-si (KR); Dongryul LEE, Yongin-si (KR); Younghoon KO, Yongin-si (KR); Sangkoan YI, Yongin-si (KR); Yujin LEE, Yongin-si (KR); Youngwoong KWON, Yongin-si (KR)

(21) Appl. No.: 19/270,648

(22) Filed: Jul. 16, 2025

(30) Foreign Application Priority Data
Sep. 13, 2024 (KR) 10-2024-0125912

(51) Int. Cl. G01R 31/392; G01R 31/367; G01R 31/3835; H01M 10/42

(52) U.S. Cl. CPC G01R 31/392; G01R 31/367; G01R 31/3835; H01M 10/4285

(57) ABSTRACT

The present disclosure relates to a method of predicting a life of a battery. The method includes calculating cumulative slippage data based on life assessment data of a battery, calculating a correlation between the cumulative slippage and a performance life of the battery, and predicting a life of the battery based on the correlation.

### CROSS-REFERENCE TO RELATED APPLICATION

This application claims priority under 35 U.S.C § 119 to Korean Patent Application No. 10-2024-0125912, filed in the Korean Intellectual Property Office on Sep. 13, 2024, the entire contents of which are hereby incorporated by reference.

### BACKGROUND

### Field

Aspects of the present disclosure relate to a device and method for predicting the life of a battery.

### Description of the Related Art

When developing a battery or secondary battery, charging and discharging can be performed repetitively under conditions and for a time that are similar to the actual usage environment of the battery so that the life of the battery is guaranteed. In this way, by having the life of a battery (or the residual rate of charge capacity) measured, the long-term life of the battery can be predicted and the life of the battery can be assessed at the same time. However, this method of assessing the life of a battery takes a long time and is cumbersome. Accordingly, it is desirable to provide a method of predicting the life of a battery that can shorten the time for assessing the life of the battery and detect the failure of the battery at an early stage.

The above information disclosed in this Background section is for enhancement of understanding of the background of the present disclosure, and therefore, it may contain information that does not constitute related (or prior) art.

### SUMMARY

An aspect of the present disclosure is to provide a device and method for predicting the life of a battery that are quicker and less cumbersome than the prior art.

These and other aspects and features of the present disclosure will be described in or will be apparent from the following description of embodiments of the present disclosure.

According to an aspect of the present disclosure, a method of predicting a life of a battery may include calculating cumulative slippage data based on life assessment data of a battery, calculating a correlation between the cumulative slippage and a performance life of the battery, and predicting a life of the battery based on the correlation.

According to some embodiments, the life assessment data may include voltage profile data on a capacity of the battery after 0 to 250 charge/discharge cycles. According to some embodiments, calculating the cumulative slippage data may include calculating cumulative capacity profile (CCP) data based on the life assessment data, and calculating the cumulative slippage based on the cumulative capacity profile (CCP) data.

According to some embodiments, the calculating the cumulative capacity profile (CCP) data may include calculating the cumulative capacity profile (CCP) data based on a plurality of charge profiles and a plurality of discharge profiles extracted from the life assessment data.

According to some embodiments, each of the charge profiles may be a voltage profile corresponding to the capacity of the battery for a single charge cycle, and each of the discharge profiles may be a voltage profile corresponding to the capacity of the battery for a single discharge cycle.

According to some embodiments, the calculating the cumulative slippage may include calculating a plurality of charge slippages and a plurality of discharge slippages based on the cumulative capacity profile (CCP) data, and calculating the cumulative slippage based on the plurality of charge slippages and the plurality of discharge slippages.

According to some embodiments, the cumulative slippage may be a sum of differences between each of the plurality of charge slippages and each of the plurality of discharge slippages.

According to some embodiments, each of the charge slippages may be an amount of change between a charge profile of a first charge cycle and a charge profile of a subsequent charge cycle, and each of the discharge slippages may be an amount of change between a discharge profile of a first discharge cycle and a discharge profile of a subsequent discharge cycle.

According to some embodiments, calculating the correlation may include calculating a correlation between the cumulative slippage and a deterioration tendency of the battery.

According to some embodiments, the calculating the correlation may include calculating a correlation between the cumulative slippage and a performance life of the battery using a linear regression model technique.

According to some embodiments, the predicting the life of the battery may include predicting a state of health (SOH) of the battery based on charge and discharge cycles based on the cumulative slippage.

According to another aspect of the present disclosure, a device for predicting a life of a battery in accordance with some embodiments of the present disclosure may include at least one processor configured to read out and execute instructions stored in a memory to cause the life prediction device to function as a data generation module configured to generate cumulative slippage data based on life assessment data of a battery, a slippage life analysis module configured to calculate a correlation between the cumulative slippage and a performance life of the battery, and a life prediction module configured to predict a life of the battery based on the correlation.

According to some embodiments, the life assessment data may include voltage profile data on a capacity of the battery after 0 to 250 charge/discharge cycles.

According to some embodiments, the data generation module may include a cumulative capacity profile calculation module configured to calculate cumulative capacity profile (CCP) data based on the life assessment data, and a slippage calculation module configured to calculate a cumulative slippage based on the cumulative capacity profile (CCP) data.

According to some embodiments, the cumulative capacity profile calculation module may be configured to calculate the cumulative capacity profile (CCP) data based on a plurality of charge profiles and a plurality of discharge profiles extracted from the life assessment data.

According to some embodiments, the slippage calculation module may be configured to calculate a plurality of charge slippages and a plurality of discharge slippages based on the cumulative capacity profile (CCP) data.

According to some embodiments, the slippage calculation module may be configured to calculate the cumulative slippage based on the plurality of charge slippages and the plurality of discharge slippages.

According to some embodiments, the slippage life analysis module may be configured to calculate a correlation between the cumulative slippage and a deterioration tendency of the battery.

According to some embodiments, the slippage life analysis module may be configured to calculate a correlation between the cumulative slippage and a performance life of the battery using a linear regression model technique.

According to some embodiments, the life prediction module may be configured to predict a state of health (SOH) of the battery based on charge and discharge cycles based on the cumulative slippage.

According to some embodiments of the present disclosure, the long-term life of a battery can be easily predicted based on charge and discharge data of initial life data of the battery.

According to some embodiments of the present disclosure, the efficiency of battery manufacturing can be improved because the life of the battery can be predicted at an early stage.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 is a block diagram describing a battery life assessment system including a battery life prediction device according to embodiments of the present disclosure.

FIG. 2 is a block diagram showing an information processing system used in the battery life assessment system according to embodiments of the present disclosure.

FIG. 3 is a block diagram describing the battery life prediction device according to embodiments of the present disclosure.

FIG. 4 is a block diagram describing the configuration of the data generation module according to embodiments of the present disclosure.

FIGS. 5 and 6 are examples describing the operation of a CCP calculation module according to embodiments of the present disclosure.

FIGS. 7a and 7b are examples describing the operation of a slippage calculation module.

FIGS. 8 and 9 are examples describing the operation of the slippage life analysis module according to embodiments of the present disclosure.

FIG. 10 is a flowchart of a life prediction method for a battery according to some embodiments.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

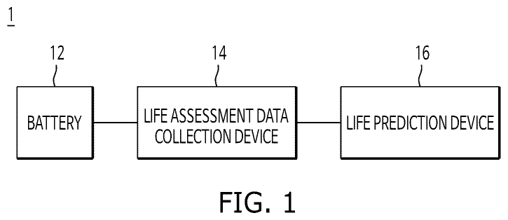

FIG. 1 is a block diagram describing a battery life assessment system 1 including a battery life prediction device 16 according to embodiments of the present disclosure.

Referring to FIG. 1, the life assessment system 1 may include a battery 12, a life assessment data collection device 14, and a life prediction device 16.

The life assessment data collection device 14 may collect life assessment data of a battery 12 from a manufacturing facility that manufactures the battery 12. For example, the life assessment data collection device 14 may collect life assessment data generated while repetitively performing charging and discharging on the battery cells by the manufacturing facility. The life assessment data may include voltage profile data on the charge capacity of the battery 12. As a specific example, the life assessment data may be voltage profile data of the battery 12 after 0 to 250 charge/discharge cycles. In other embodiments, the life assessment data collection device 14 may include a charge/discharge module capable of performing charging/discharging of the battery 12 manufactured by the manufacturing facility, and a data collection module that collects life assessment data generated while repetitively charging and discharging on the battery 12 using the charge/discharge module.

The life prediction device 16 may calculate slippage-related data based on the life assessment data. Here, the slippage refers to the amount of change in capacity in the cumulative capacity-voltage profile data. For example, a charge slippage may refer to the amount of change in charge capacity in the cumulative capacity-voltage profile data. As another example, a discharge slippage may refer to the amount of change in discharge capacity in the cumulative capacity-voltage profile data.

The life prediction device 16 may predict the life of the battery 12 based on the slippage-related data. Here, the life prediction device 16 may predict the life of the battery 12 based on the correlation between the slippage-related data including the cumulative slippage and the deterioration tendency of the battery 12. The deterioration tendency may include, but is not limited to, a point of a sudden decline and a point of end of life (EOL) of the battery 12. The deterioration tendency may include all characteristics indicative of a deterioration tendency according to the life of the battery 12.

The correlation between the cumulative slippage and the performance life of the battery 12 may be calculated using a linear regression model technique. Further, the life prediction device 16 may predict the state of health (SOH) of the battery 12 according to the charge/discharge cycle based on the correlation. The life predicted by the life prediction device 16 may be used to assess the life quality of the battery 12.

As described above, the battery life assessment system 1 according to embodiments of the present disclosure can easily predict the long-term life of a battery based on the initial life data of the battery.

According to embodiments of the present disclosure, as the battery life assessment system 1 can predict the life of the battery, the quality of the battery cells can be assessed at an early stage, and the efficiency of battery manufacturing can be improved.

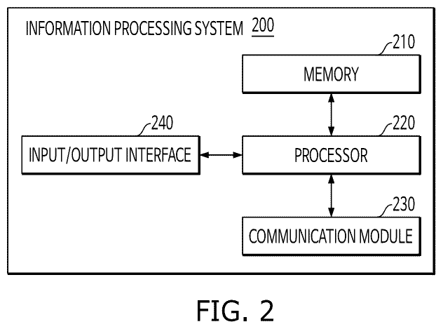

FIG. 2 is a block diagram showing an information processing system 200 used in the battery life assessment system 1 according to embodiments of the present disclosure.

Referring to FIG. 2, the information processing system 200 may correspond to one or more of the battery life assessment system 1 and the life prediction device 16 shown in FIG. 1. The information processing system 200 may include a memory 210, a processor 220, a communication module 230, and an input/output interface 240. Referring to FIG. 2, the information processing system 200 may be configured to communicate information and/or data over a network using the communication module 230. In embodiments, the information processing system 200 may be embodied as at least one device including the memory 210, the processor 220, the communication module 230, and the input/output interface 240.

The memory 210 may include any non-transitory computer-readable recording medium. In some embodiments, the memory 210 may include a permanent mass storage device, such as read-only memory (ROM), a disk drive, a solid-state drive (SSDs), flash memory, etc. As another example, the permanent mass storage device, such as ROM, SSD, flash memory, a disk drive, etc., may be included in the information processing system 200 as a separate persistent storage device distinct from the memory 210. Further, the memory 210 may store software components including an operating system and at least one program code, such as code for implementing a slippage life analysis module and a life prediction module installed and run in the information processing system 200.

These software components may be loaded from a computer-readable recording medium separate from the memory 210. Such a separate computer-readable recording medium may include a recording medium directly connectable to the information processing system 200, and may include, for example, computer-readable recording media such as floppy drives, disks, tapes, DVD/CD-ROM drives, memory cards, etc. As another example, the software components may be loaded into the memory 210 via the communication module 230 rather than computer-readable recording media. At least one program may be loaded onto the memory 210 based on a computer program (e.g., programs for implementing a slippage life analysis module and a life prediction module, etc.) installed by files provided via the communication module 230 by developers or a file distribution system that distributes installation files of an application.

The processor 220 may be configured to process commands of computer programs by performing basic arithmetic, logic, and input/output operations. The commands may be provided to a user terminal (not shown) or another external system by the memory 210 or the communication module 230. For example, the processor 220 may collect life assessment data of the battery from one or more manufacturing facilities, generate cumulative slippage data based on the life assessment data, calculate a correlation between the cumulative slippage and the performance life of the battery, and then predict the life of the battery based on the correlation.

The communication module 230 may provide a configuration or function for the user terminal (not shown) and the information processing system 200 to communicate with each other via a network. The communication module 230 may also provide a configuration or function for the information processing system 200 to communicate with an external system such as a manufacturing facility for the battery, a separate cloud system, etc. In some embodiments, control signals, commands, data, etc., provided under the control of the processor 220 of the information processing system 200 may be transmitted to the user terminal and/or the external system by way of the communication module 230 and the network via the communication module of the user terminal and/or the external system. For example, the predicted life information of the battery, etc., generated by the information processing system 200 may be transmitted to the user terminal and/or the external system by way of the communication module 230 and the network via the communication module of the user terminal and/or the external system. Further, the user terminal and/or the external system that has received the predicted battery life information may output the received information via a display device.

The input/output interface 240 of the information processing system 200 may be a means for interfacing with devices (not shown) for input or output that may be connected to the information processing system 200 or that may be included with the information processing system 200. In FIG. 2, the input/output interface 240 is shown as an element configured separately from the processor 220 but is not limited thereto, and the input/output interface 240 may be included in the processor 220. The information processing system 200 may include more components than those in FIG. 2.

The processor 220 of the information processing system 200 may be configured to manage, process, and/or store information and/or data received from a plurality of user terminals and/or a plurality of external systems. According to some embodiments, the processor 220 may receive the life assessment data of the battery from the user terminal and/or the external system. The processor 220 may calculate a cumulative slippage based on the life assessment data of the battery, predict the life of the battery based on the calculated cumulative slippage, and then output the corresponding life prediction information via a display device connected to the information processing system 200.

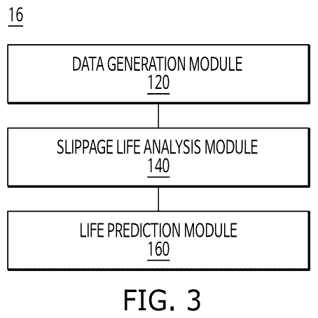

FIG. 3 is a block diagram describing the battery life prediction device 16 according to embodiments of the present disclosure.

Referring to FIG. 3, the life prediction device 16 may include a data generation module 120, a slippage life analysis module 140, and a life prediction module 160.

In embodiments, the data generation module 120 may generate cumulative slippage data based on the life assessment data of the battery. Here, the cumulative slippage may be calculated based on cumulative capacity profile (CCP) data. The cumulative capacity profile (CCP) data may be data obtained by accumulating a plurality of charge capacity-voltage profiles and a plurality of discharge capacity-voltage profiles.

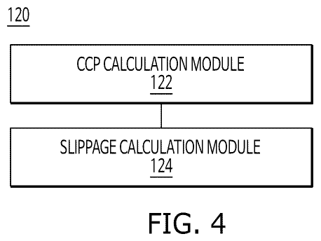

The specific configuration of the data generation module 120 will be described in detail with reference FIGS. 4 to 7b.

The slippage life analysis module 140 may calculate a correlation between the cumulative slippage and the deterioration tendency of the battery. Here, the deterioration tendency may include a point of a sudden decline and a point of EOL of the battery 12. The point of a sudden decline may refer to a cycle point at which the slope of the state of health (SOH) for the battery decreases rapidly due to rapid deterioration of the battery. Based on the correlation described above, the life analysis module 140 may calculate the correlation between the cumulative slippage and the performance life of the battery.

The slippage life analysis module 140 may calculate a correlation between the cumulative slippage and the performance life of the battery using a linear regression model technique. However, the present disclosure is not limited thereto. For example, the performance life of the battery may be included in the life assessment data of the corresponding battery. Here, the performance life may refer to a life cycle when the state of health (SOH) of the battery is between 85% and 75%. Preferably, the performance life may be, but is not limited to, a life cycle when the state of health (SOH) of the battery is 80%. Here, the point at which the state of health (SOH) of the battery is 80% may be an EOL point of the battery.

The cumulative slippage may be calculated from the accumulated charge slippage and discharge slippage when the number of life cycles of the battery is in the range of 0 to 250. Preferably, the cumulative slippage may be calculated in the range of 0 to 100 life cycles of the battery. But the present disclosure is not limited thereto.

The cumulative slippage may have linearity with respect to the performance life, and the slippage analysis module 140 may calculate a correlation having such linearity. Accordingly, the slippage analysis module 140 may calculate a performance life or state of health corresponding to a particular cumulative slippage of the battery based on the correlation having such linearity.

The slippage analysis module 140 may calculate a correlation according to a linear regression model in advance based on data on the cumulative slippage and performance life of a plurality of batteries. Then, the slippage analysis module 140 may store the correlation calculation and calculate a correlation between the cumulative slippage and the performance life of the battery based thereon. In some embodiments, the life prediction module 160 may predict the state of health (SOH) of the battery according to the charge/discharge cycle based on the correlation between the cumulative slippage and the performance life calculated by the life analysis module 140.

The battery life assessment system 1 according to some embodiments of the present disclosure can easily predict the long-term life of a battery based on the cumulative slippage, which is the initial life data of the battery.

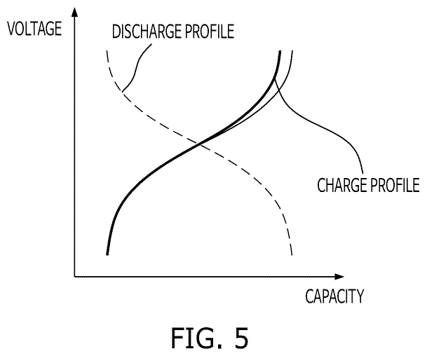

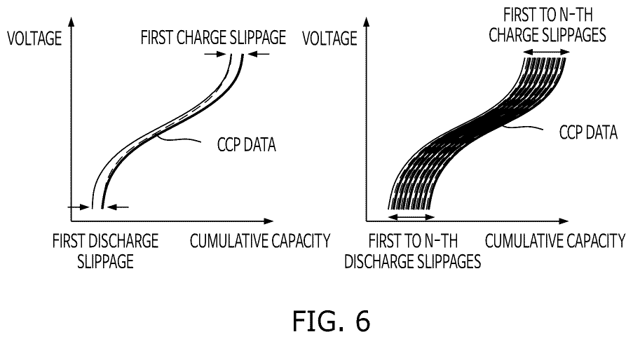

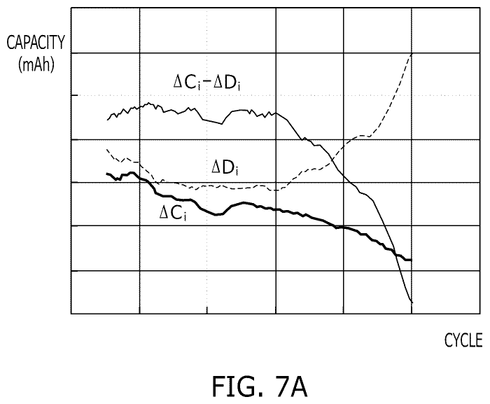

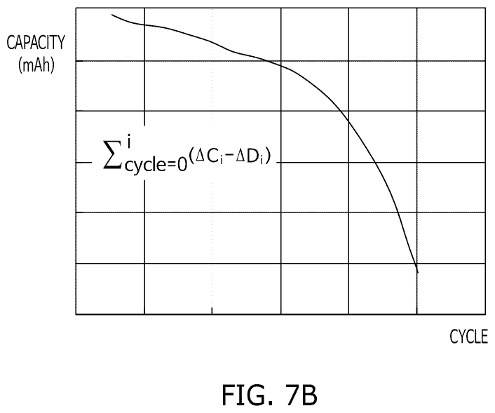

FIG. 4 is a block diagram describing the configuration of the data generation module 120 according to embodiments of the present disclosure. FIGS. 5 and 6 are examples describing the operation of a CCP calculation module 122 according to embodiments of the present disclosure, and FIGS. 7a and 7b are examples describing the operation of a slippage calculation module 124.

Referring to FIG. 4, the data generation module 120 may include the CCP calculation module 122 and the slippage calculation module 124.

In some embodiments, the CCP calculation module 122 may calculate cumulative capacity profile data based on the life assessment data. For example, referring to FIG. 5, a plurality of charge profiles and discharge profiles showing changes in charge and discharge voltages according to changes in the charge capacity of the battery may be measured. Of these, each of the plurality of charge profiles may be a voltage profile according to the capacity of the battery for one charge cycle. Further, each of the plurality of discharge profiles may be a voltage profile according to the capacity of the battery for one discharge cycle.

Referring to FIG. 6, the CCP calculation module 122 may calculate cumulative capacity profile (CCP) data based on the plurality of charge profiles and the plurality of discharge profiles extracted from the life assessment data. Further, the slippage calculation module 124 may calculate a cumulative slippage based on the cumulative capacity profile (CCP) data.

The slippage calculation module 124 may calculate a plurality of charge slippages and a plurality of discharge slippages based on the cumulative capacity profile (CCP) data. Referring to FIGS. 7a and 7b, each of the plurality of charge slippages may be the amount of change between the charge profile of a first charge cycle and the charge profile of a subsequent cycle of the first charge cycle. That is, the i-th charge slippage AC_i may be the amount of change between the (i+1)th charge profile C_i+1 and the i-th charge profile C_i. Further, each of the plurality of discharge slippages may be the amount of change between the discharge profile of a first discharge cycle and the discharge profile of a subsequent cycle of the first discharge cycle. That is, the i-th discharge slippage AD_i may be the amount of change between the (i+1)th discharge profile D_i+1 and the i-th discharge profile D_i.

The slippage calculation module 124 may calculate the cumulative slippage based on the plurality of charge slippages AC and the plurality of discharge slippages AD. Here, the cumulative slippage may be the sum of the difference values AC-AD between each of the plurality of charge slippages AC and each of the plurality of discharge slippages AD. That is, the cumulative slippage may be expressed as

$${\sum }_{c y c l e = 0}^{i} ( ΔC\_i - ΔD\_i ) .$$

In some embodiments, the slippage calculation module 124 may use the life assessment data when the number of life cycles of the battery is in the range of 0 to 250. Accordingly, the slippage calculation module 124 may calculate the cumulative slippage after 0 to 250 life cycles.

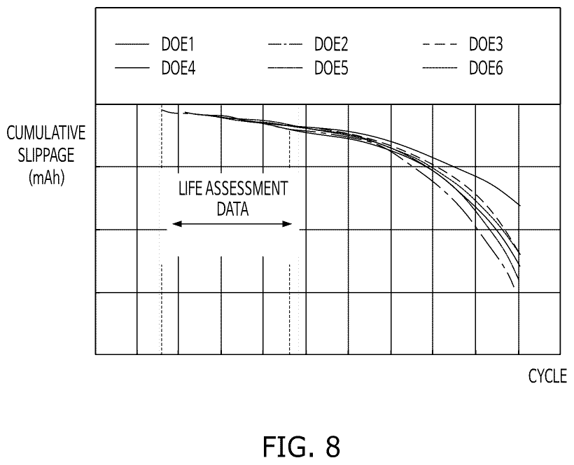

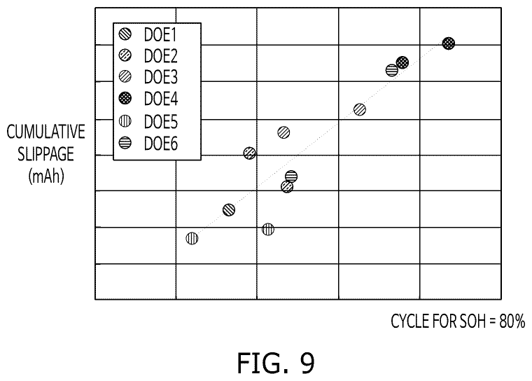

FIGS. 8 and 9 are examples describing the operation of the slippage life analysis module 140 according to embodiments of the present disclosure.

Referring to FIG. 8, the data generation module 120 may calculate a cumulative slippage according to a predetermined life cycles of the battery. Here, the number of predetermined life cycles may be 70 to 250, which is the range of the initial life cycle of the battery. In such a case, the cumulative slippage may be calculated based on the initial life data of the battery. FIG. 8 shows a plurality of design of experiments (DOE), and (DOE represents a cumulative slippage calculated for the life assessment data in the range of 70 to 250 life cycles of different experimental batteries. The data generation module 120 may transfer the calculated cumulative slippage to the life analysis module 140. Further, the life analysis module 140 may receive the life assessment data, and the life analysis module 140 may extract a performance life from the life assessment data. Here, the performance life may be a life cycle when the state of health (SOH) of the battery is 80%. Moreover, the point at which the state of health (SOH) of the battery is 80% may be an EOL point of the battery.

Referring to FIG. 9, the life analysis module 140 may calculate a correlation between the cumulative slippage and the performance life. FIG. 9 shows the correlation calculated by the life analysis module 140 based on the linearity between the cumulative slippage and the performance life calculated for a plurality of experimental data DOE1 to DOE6. Here, the performance life may be a life cycle when the state of health (SOH) is 80%. However, such a performance life is merely one example and the present disclosure is not limited thereto. Then, the life analysis module 140 may transfer the correlation between the calculated cumulative slippage and the performance life to the life prediction module 160. Then, the life prediction module 160 may predict the state of health (SOH) according to the charge/discharge cycle of the battery based on the correlation between the cumulative slippage and the performance life calculated by the life analysis module 140.

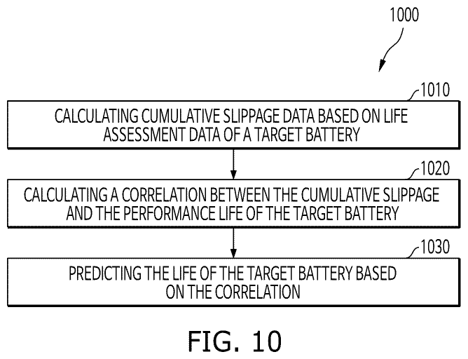

FIG. 10 is a flowchart of a life prediction method 1000 for a battery according to some embodiments.

Referring to FIG. 10, the life prediction method 1000 may be executed by the life prediction device 16 of FIG. 3.

The life prediction method 1000 may begin with calculating cumulative slippage data based on life assessment data of a battery (1010). For example, the data generation module 120 of FIG. 3 may calculate cumulative slippage data based on the life assessment data of the battery. Here, the life assessment data may include voltage profile data on the capacity of the battery after 0 to 250 charge/discharge cycles.

According to some embodiments, the calculating the cumulative slippage data (1010) may include calculating cumulative capacity profile (CCP) data based on the life assessment data, and calculating a cumulative slippage based on the cumulative capacity profile (CCP) data. Further, the calculating the cumulative capacity profile (CCP) data may include calculating the cumulative capacity profile (CCP) data based on a plurality of charge profiles and a plurality of discharge profiles extracted from the life assessment data. Moreover, the calculating the cumulative slippage may include calculating a plurality of charge slippages and a plurality of discharge slippages based on the cumulative capacity profile (CCP) data, and calculating the cumulative slippage based on the plurality of charge slippages and the plurality of discharge slippages.

Then, a correlation between the cumulative slippage and the performance life of the battery may be calculated (1020). For example, the life analysis module 140 of FIG. 3 may calculate the correlation between the cumulative slippage and the performance life.

The calculating the correlation (1020) may include calculating a correlation between the cumulative slippage and a deterioration tendency of the battery. In other embodiments, the calculating the correlation (1020) may include calculating a correlation between the cumulative slippage and the performance life of the battery using a linear regression model technique.

Accordingly, the life of the battery may be predicted based on the correlation (1030). For example, the life prediction module 160 of FIG. 3 may predict the life of the battery based on the calculated correlation.

According to embodiments of the present disclosure, the predicting the life of the battery (1030) may include predicting a state of health (SOH) of the battery according to a charge/discharge cycle based on the cumulative slippage.

Although the present disclosure has been described with reference to embodiments and drawings illustrating aspects thereof, the present disclosure is not limited thereto. Various modifications and variations can be made by a person skilled in the art to which the present disclosure belongs.

### DESCRIPTION OF SOME REFERENCE SYMBOLS

1: Battery life assessment system
12: Battery
14: Life assessment data collection device
16: Life prediction device
120: Data generation module
122: CCP calculation module
124: Slippage calculation module
140: Slippage life analysis module
160: Life prediction module
200: Information processing system
210: Memory
220: Processor
230: Communication module
240: Input/output interface

What is claimed is:

1. A method of predicting a life of a battery, the method comprising:
calculating cumulative slippage data based on life assessment data of a battery;
calculating a correlation between the cumulative slippage and a performance life of the battery; and
predicting a life of the battery based on the correlation.

2. The method as claimed in claim 1, wherein the life assessment data comprises voltage profile data of a capacity of the battery after 0 to 250 charge/discharge cycles.

3. The method as claimed in claim 2, wherein the calculating the cumulative slippage data comprises:
calculating cumulative capacity profile data based on the life assessment data; and
calculating the cumulative slippage based on the cumulative capacity profile data.

4. The method as claimed in claim 3, wherein calculating the cumulative capacity profile (CCP) data comprises calculating the cumulative capacity profile data based on a plurality of charge profiles and a plurality of discharge profiles extracted from the life assessment data.

5. The method as claimed in claim 4, wherein each of the charge profiles is a voltage profile corresponding to the capacity of the battery for a single charge cycle, and
wherein each of the discharge profiles is a voltage profile corresponding to the capacity of the battery for a single discharge cycle.

6. The method as claimed in claim 5, wherein the calculating the cumulative slippage comprises:
calculating a plurality of charge slippages and a plurality of discharge slippages based on the cumulative capacity profile data; and
calculating the cumulative slippage based on the plurality of charge slippages and the plurality of discharge slippages.

7. The method as claimed in claim 6, wherein the cumulative slippage is a sum of differences between each of the plurality of charge slippages and each of the plurality of discharge slippages.

8. The method as claimed in claim 7, wherein each of the charge slippages is an amount of change between a charge profile of a first charge cycle and a charge profile of a subsequent charge cycle, and
each of the discharge slippages is an amount of change between a discharge profile of a first discharge cycle and a discharge profile of a subsequent discharge cycle.

9. The method as claimed in claim 8, wherein calculating the correlation comprises calculating a correlation between the cumulative slippage and a deterioration tendency of the battery.

10. The method as claimed in claim 9, wherein the calculating the correlation comprises calculating a correlation between the cumulative slippage and a performance life of the battery using a linear regression model technique.

11. The method as claimed in claim 10, wherein the predicting the life of the battery comprises predicting a state of health (SOH) of the battery based on charge and discharge cycles based on the cumulative slippage.

12. A device for predicting a life of a battery, the device comprising:
at least one processor configured to read out and execute instructions stored in a memory to cause the life prediction device to function as:
a data generation module configured to generate cumulative slippage data based on life assessment data of a battery;
a slippage life analysis module configured to calculate a correlation between the cumulative slippage and a performance life of the battery; and
a life prediction module configured to predict a life of the battery based on the correlation.

13. The device as claimed in claim 12, wherein the life assessment data comprises voltage profile data on a capacity of the battery after 0 to 250 charge/discharge cycles.

14. The device as claimed in claim 13, wherein the data generation module comprises:
a cumulative capacity profile calculation module configured to calculate cumulative capacity profile data based on the life assessment data; and
a slippage calculation module configured to calculate a cumulative slippage based on the cumulative capacity profile data.

15. The device as claimed in claim 14, wherein the cumulative capacity profile calculation module is configured to calculate the cumulative capacity profile data based on a plurality of charge profiles and a plurality of discharge profiles extracted from the life assessment data.

16. The device as claimed in claim 15, wherein the slippage calculation module is configured to calculate a plurality of charge slippages and a plurality of discharge slippages based on the cumulative capacity profile data.

17. The device as claimed in claim 16, wherein the slippage calculation module is configured to calculate the cumulative slippage based on the plurality of charge slippages and the plurality of discharge slippages.

18. The device as claimed in claim 17, wherein the slippage life analysis module is configured to calculate a correlation between the cumulative slippage and a deterioration tendency of the battery.

19. The device as claimed in claim 18, wherein the slippage life analysis module is configured to calculate a correlation between the cumulative slippage and a performance life of the battery using a linear regression model technique.

20. The device as claimed in claim 19, wherein the life prediction module is configured to predict a state of health of the battery based on charge and discharge cycles based on the cumulative slippage.
